(19) United States
(12) Patent Application Publication
(10) Pub. No.: US 2009/0177595 A1
(43) Pub. Date: Jul. 9, 2009

(54) Bidirectional metering and control of electric energy between the power grid and vehicle power systems

(76) Inventors: Stephen David Dunlap, Richardson, TX (US); William Bennett Morrow, Plano, TX (US); Jacqueline Frances Timte, Plano, TX (US)

Correspondence Address: Law Office of ROBERT C. KLINGER, 2591 Dallas Parkway, Suite 300, FRISCO, TX, 75034, US

(21) Appl. No.: 12/287,105

(22) Filed: Oct. 6, 2008

Related U.S. Application Data
(60) Provisional application No. 61/019,658, filed on Jan. 8, 2008.

(51) Int. Cl. G06Q 30/00; G01R 21/00; H02J 7/02; G06F 17/30; G06Q 50/00

(52) U.S. Cl. 705/412; 702/62; 320/109; 707/104.1; 707/E17.044

(57) ABSTRACT

A metering device that allows the two-way exchange of electrical energy between the power grid and electric vehicles by giving customers the option to upload electrical energy from their vehicle's electrical power system to the power grid or to another vehicle, or the option to download electrical energy from the power grid or another vehicle, to charge their vehicle's electric storage system, depending on the current market price of electricity. This allows users to both buy and sell electricity as a commodity to offset their fuel costs and to generate income. The metering device and the associated server may maintain a database of the user's preferences and identification. The metering device may allow customers to upload and sell electricity from their vehicles during peak, high cost, energy consumption periods, download and buy electricity to their vehicles during low energy, low cost, consumption periods, or algorithmically engage in bi-directional transfer depending on the user's preferences and other variables (see [0043]) in order to maximize the customer's monetary returns and minimize the customer's monetary expenses.

### CLAIM OF PRIORITY

This patent claims priority of U.S. Provisional 61/019,658 entitled IMPROVEMENTS IN TRANSFER OF ELECTRIC. ENERGY BETWEEN THE GRID AND ELECTRIC POWERED VEHICLES, filed Jan. 8, 2008 the teachings of which are incorporated herein by reference.

### FIELD OF THE INVENTION

The present invention relates to method and apparatus for the exchange of electrical energy between the power grid and vehicles propelled by an electric motor. The term “vehicle” may be applicable to, but not limited to, scooters, bicycles, automobiles, motorcycles, trains, watercraft, sailcraft, aircraft, hovercraft, and spacecraft. The term “electrical power system” may comprise, but is not limited to, storage systems such as electrochemical storage devices, batteries, fuel cells, and capacitors, and generating devices such as turbines, solar panels, and reactors.

### BACKGROUND OF THE INVENTION

As the world ushers in a new era of electric propulsion in vehicles, a connection between those vehicles and the power grid will form. Currently, vehicles powered with electrical power systems may be charged by connecting to a power transfer facility. However, electrical outlets and charging stations are limited in availability. It is not convenient, and sometimes impossible, to wait until arriving at home to charge a vehicle's electric storage powered on, but are not producing any electricity) for unscheduled increases in demand. The current approach to meeting this demand is inefficient and inconsistent. It requires a large amount of wasted energy and is “dirty” because coal-fired, petroleum-fired, and gas-fired power plants account for 69% of the power plants in the United States.

### SUMMARY OF INVENTION

The present invention achieves technical advantages by providing a two-way device that facilitates both uploading electrical energy from a vehicle to a power grid or another vehicle, or downloading energy to the vehicle. The device monitors and measures the exchanged electric current in real time. The device also controls the current between the vehicle and the power grid or another vehicle. An associated management system records the identity of the vehicle and maintains a record of the associated transfer. The device is configured to communicate with other devices, including servers, through a communication protocol. The device may obtain the amount of charge in the vehicle's electrical power system and then may use the information as a variable in determining the rate and direction of power flow. The user's identity can be authenticated through unique information supplied by the user. This unique identifier links the user's measured interaction with the device to their account in the database, the user will participate directly in the buying and selling electric energy.

### BRIEF DESCRIPTION OF THE DRAWINGS

Advantages of the invention and the specific embodiments will be understood by those of ordinary skill in the art by reference to the following detailed description of preferred embodiments taken in conjunction with the drawings, in which:

FIG. 1 shows an overview block diagram of the power flow and data transmission in accordance with one aspect of the present invention;

FIG. 2 shows a block diagram of an exemplary embodiment of a uni-directional metering device in accordance with the present invention;

FIG. 3 shows a block diagram of an exemplary embodiment of a bi-directional metering device in accordance with the present invention;

FIG. 4 shows a front view of a metering device in accordance with the present invention;

FIG. 5 shows a side view of a metering device in accordance with the present invention;

FIG. 6 shows a high level flow diagram of the user experience with the metering device in accordance with the present invention;

FIG. 7 shows a detailed flow diagram of the customer identification methodology in accordance with the present invention;

FIG. 8 shows a detailed flow diagram of the power transfer methodology in accordance with the present invention;

FIG. 9 shows a detailed flow diagram of the power transfer method options in accordance with the present invention.

### DETAILED DESCRIPTION OF THE PRESENT INVENTION

The numerous innovative teachings and aspects of the present invention will be described with particular reference to the following exemplary embodiments. However, it should be understood that this class of embodiments provides only a few examples of the many advantageous uses and innovative teachings of the inventor. In general, statements made in the specification of the present application do not necessarily delimit any of the various claimed inventions. Moreover, some statements may apply to some inventive features, but not to others.

In accordance with an aspect of the invention, devices embodying the invention may be placed, for instance in the parking garages of office buildings and airports and at residential homes where people leave their vehicles idle for long periods. Electric vehicles participate in power grid regulation, act as a generator in times of emergency strain on the power plant, or simply sell power to the grid or other vehicles through the metering device when the demand-based price is desirable. The power company is willing to pay a high price for this electricity because it is cheaper than the cost of keeping additional generators on reserve. The business operating these devices can obtain a contracted premium price per megawatt provided from power companies. The business can return some of the price to the vehicle owners and location owners based on the amount of electricity they supply.

In addition, the invention may be placed in parking lots of restaurants, retail outlets, and grocery stores where people leave their vehicles for short durations. This way, batteries can recharge conveniently while people shop or eat dinner. Landlords will gladly accept the devices on their property because they will earn revenue and will be eligible to receive a tax-break for installing “green” products.

Device users may identify themselves through a unique identifier. This identifier could be, but is not restricted to, RFID tags, biometrics, credit card, or government issued identification. With this information, the company can verify the customer's account in a database. The user may create this account through an online website or telephone call. The account information may include vehicle information, billing information, driving habits, or other personal data. This allows for the reduction of physical transaction time at the device while authenticating the vehicle owner's identity for billing and back-end data collection.

In the home market, members of the public can lease the devices. Under the assumption that vehicle owners plug their vehicle at home or work for a total of 18 hours each day, the owner can sell several thousand dollars of electricity per year back to the grid. This additional revenue could more than pay for the customer's average annual fuel consumption.

The potential customer base for the invention contains three branches: vehicle owners, power companies, and office and retail parking area landlords. Each of these parties attempts to curtail high energy demands in their own way. Current vehicle owners are concerned with high gas prices and fuel efficiency. Power companies have diversified into wind and hydro-electric power generation while consumers install solar panels and use more energy efficient products. These-avenues, however, are limited in their ability to store energy, or in the case of wind energy, are simply unreliable. The device provides an avenue free from these limitations.

The device works with the established industry standards, requiring no special electrical plugs or set up. The system is not dependent on third parties bundling proprietary software or hardware into their products, such as automakers bundling software into new electric vehicles. This allows for as many customers as possible to use the devices and system.

Wireless power transfer from the vehicle to the grid is a viable alternative to plugging-in. Also, communicating between the device and the vehicle will become more feasible as automobile wired and wireless communication standards mature.

The system allows customers to use it wherever the devices are installed, so they do not have to remain in one geographic area to benefit from the devices. The metering device may also be freestanding or attached to another object such as a light pole.

The device may provide connections to all electric vehicles with a power exchange standard regardless of the vehicle manufacturer or the construction of the vehicle electrical power system.

Customers can use the devices embodying this invention by simply providing unique identification, establishing an electrical connection, and inputting configuration details. Everything else would be handled by the device and servers comprising the system.

This solution to high energy demand and dependency of foreign oil utilizes the potential of electric-powered vehicles. By simply establishing a power connection to the device, consumers will conserve energy and make money at the same time.

In another aspect, the invention provides the infrastructure for vehicle-to-grid technology. The electric and data connections made through the device will bring benefits to the parties involved. Power companies will spend less on generators and fuel. Parking garage landlords will receive government tax breaks for “going green,” and will give employees the benefit of making money through their vehicle while at work. By providing accessible charging stations for electric-powered vehicles, retailers will drive more consumers to their stores and see an increase in shoppers' duration in their stores as the shoppers charge their vehicles.

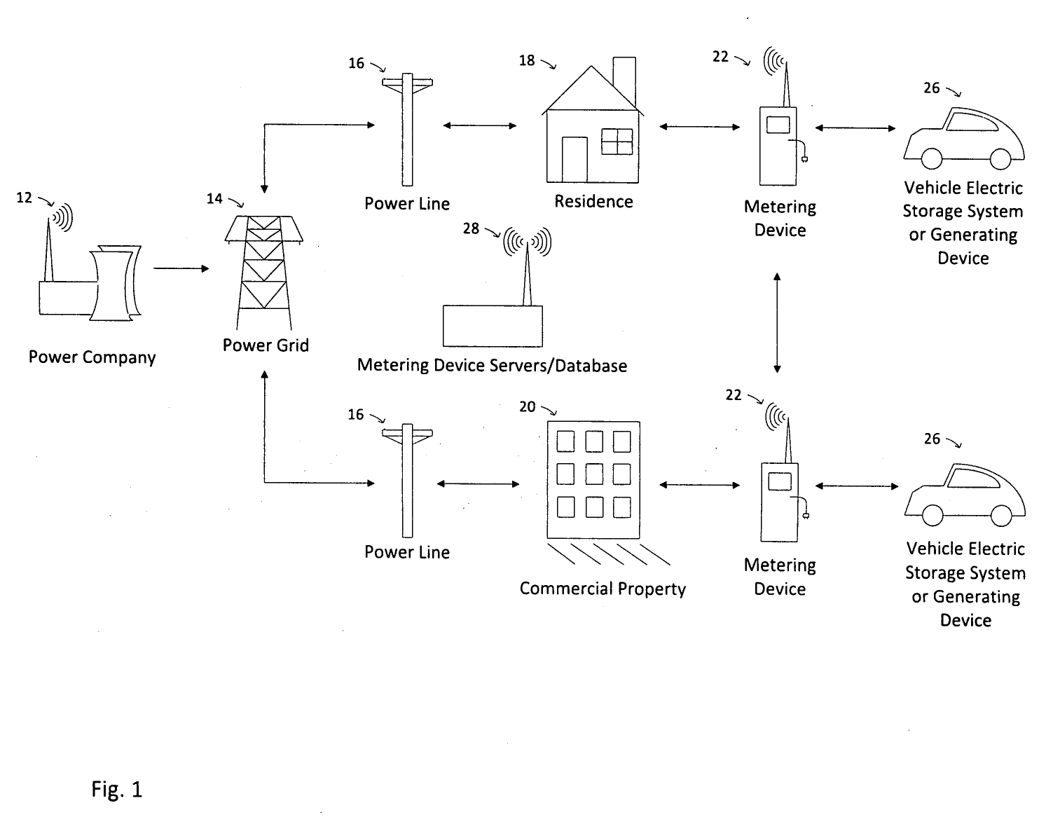

Turning now to FIG. 1, there is shown an overview block diagram of the power flow and data transmission 10 in accordance with one aspect of the present invention. Power flow is shown by arrows and data transmission is represented by the lines emanating from the wireless towers, although data transmission does not have to be wireless and may occur over any data connection. Power flow originates from a power company 12 and is transmitted to a power grid 14, and then through a power line 16, and on to a residential home 18 or a commercial property 20 where a metering device 22 is installed. A customer parks his vehicle next to the metering device 22 and establishes a connection between a vehicle electrical power system 26 and the metering device 22. The metering device 22 can either download and purchase electric current from the power grid 14 to charge the vehicle electrical power system 26 or upload and sell electric current from the vehicle electrical power system 26 back to the power grid 14. The buying and selling of electric current may also take place between two vehicles 26 through two metering devices 22.

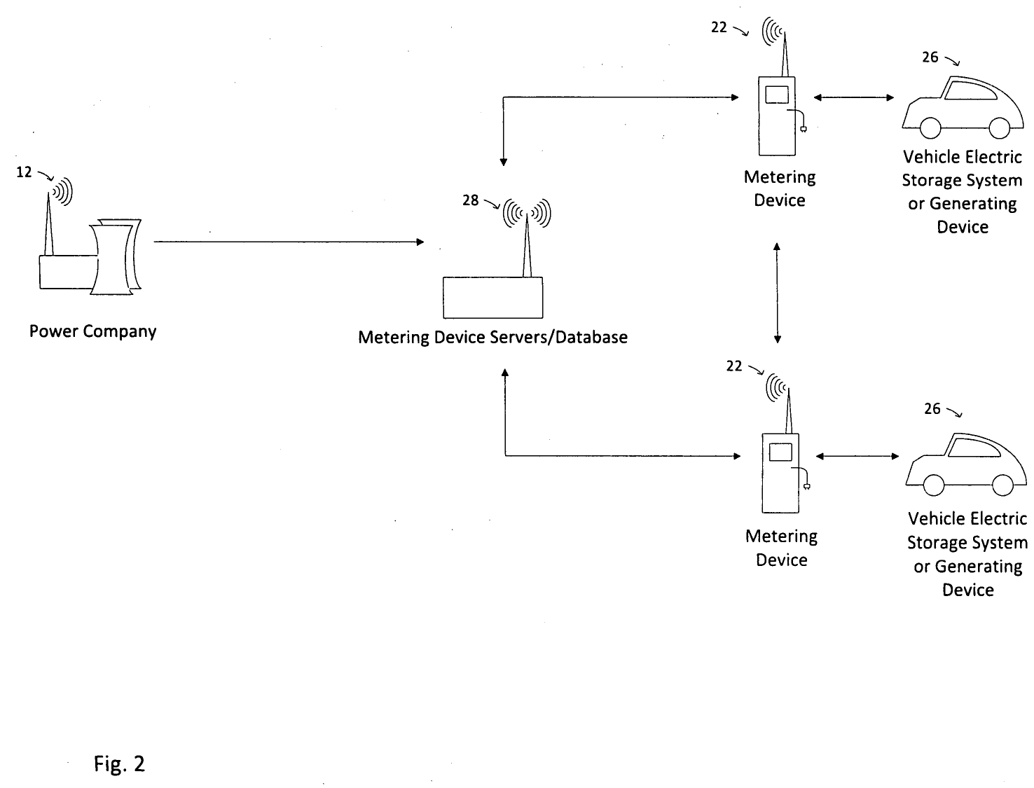

Referring now to FIG. 2, data is transferred between the power company 12, the metering device 22, a metering device server/database 28, and vehicles 26 and may be transferred over any data connection in accordance with one aspect of the present invention. This data may encompass, but is not limited to, user account information, command functions, logs and history information, video files, audio files, executable files, and configuration files. Data transfers may also be used as a form of payment or currency, such as vehicle owners receiving a MP3 in exchange for the power they transferred. Both the power company 12 and the metering device 22 measure and record the amount of current transferred either from the power grid through the metering device 22 to the vehicle 26, in which case the customer's account is debited for downloading power, or from the vehicle 26 through the metering device 22 and back to the power grid or another vehicle, in which case the customer's account is credited for uploading power, and that information is transmitted to the servers/database 28 for recordation.

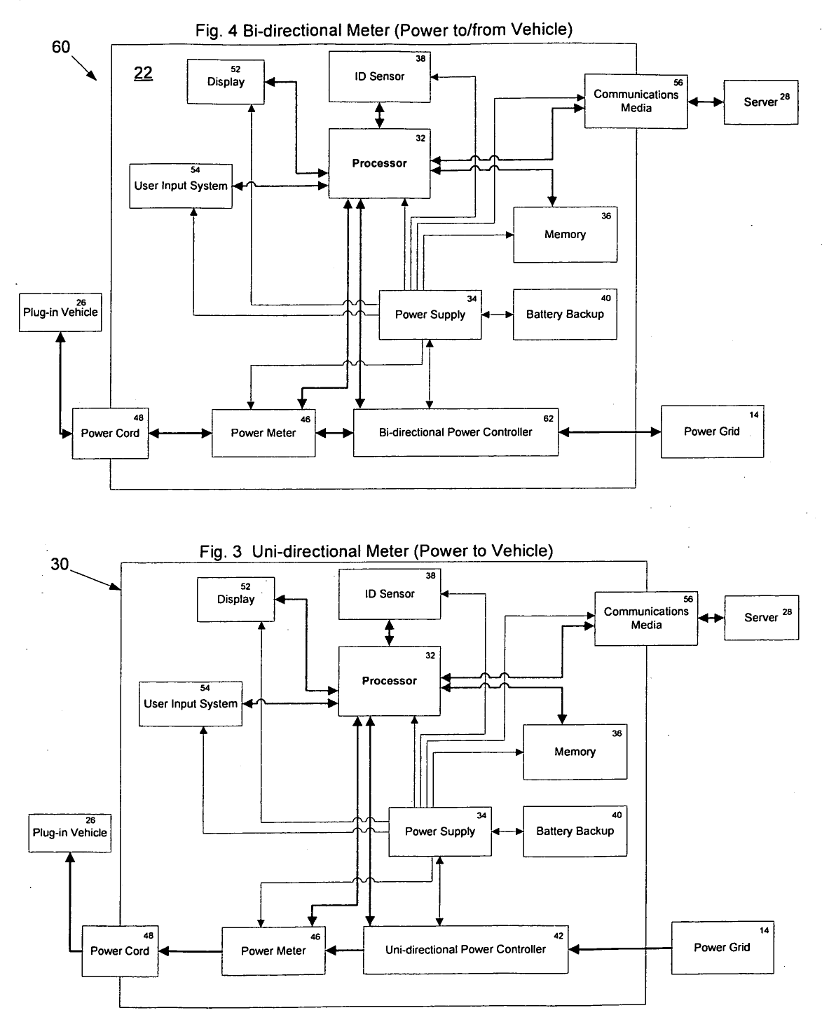

Referring now to FIG. 3, there is shown a block diagram 30 of an exemplary embodiment of an uni-directional metering device 22 capable of downloading power from the power grid 14 through the metering device 22 to the vehicle electrical power system 26 as depicted in FIG. 1 and in accordance with one aspect of the present invention. A power supply 34 powers a CPU 32, a memory 36, a identification sensor 38, a battery backup 40, which also acts as a backup power supply, an uni-directional power controller 42, a power meter 46, a communications media 56, a display 52, and an user input system 54. The CPU 32 is powered by the power supply 34 and communicates with and controls the memory 36, the identification sensor 38, the uni-directional power controller 42, the power meter 46, the display 52, the user input system 54, and the communications media 56. Power from the power grid 14 enters the uni-directional metering device 22 through the uni-directional power controller 42, which downloads power from the power grid 14 through the power meter 46 to a power cord 48 and to the vehicle electrical power system 26. The recorded amount of electric current downloaded to the vehicle electrical power system 26 is stored in memory 36. The CPU 32 can then direct that information to the communications media 56 which transmits the information over the data connection to the metering device server/database 28.

Referring now to FIG. 4, there is shown a block diagram 60 of an exemplary embodiment of a bi-directional metering device 22 capable of downloading power from the power grid 14 through the metering device 22 to the vehicle electrical power system 26 or uploading power from the vehicle electrical power system 26 through the metering device 22 and back to the power grid 14 or to another vehicle electrical power system as depicted in FIG. 1 and in accordance with one aspect of the present invention. The power supply 34 powers the CPU 32, the memory 36, the identification sensor 38, the battery backup 40, which also acts as a backup power supply, a bi-directional power controller 62, the power meter 46, the communications media 56, the display 52, and the user input system 54. The CPU 32 is powered by the power supply 34 and communicates with and controls the memory 36, the identification sensor 38, the bi-directional power controller 62, the power meter 46, the display 52, the user input system 54, and the communications media 56. Power from the power grid 14 enters the bi-directional metering device 22 through the bi-directional power controller 62, which either downloads power from the power grid 14 through the power meter 46 to a power cord 48 and to the vehicle electrical power system 26 or uploads power from the vehicle electrical power system 26 by the power cord 48 through the power meter 46 to the bi-directional power controller 62 and back to the power grid 14. The amount of electric current downloaded to the vehicle electrical power system 26, or uploaded to the power grid 14 or other metering device 22 is stored in memory 36. The CPU 32 then directs that information to the communications media 56 which transmits the information over the data connection to the metering device server/database 28.

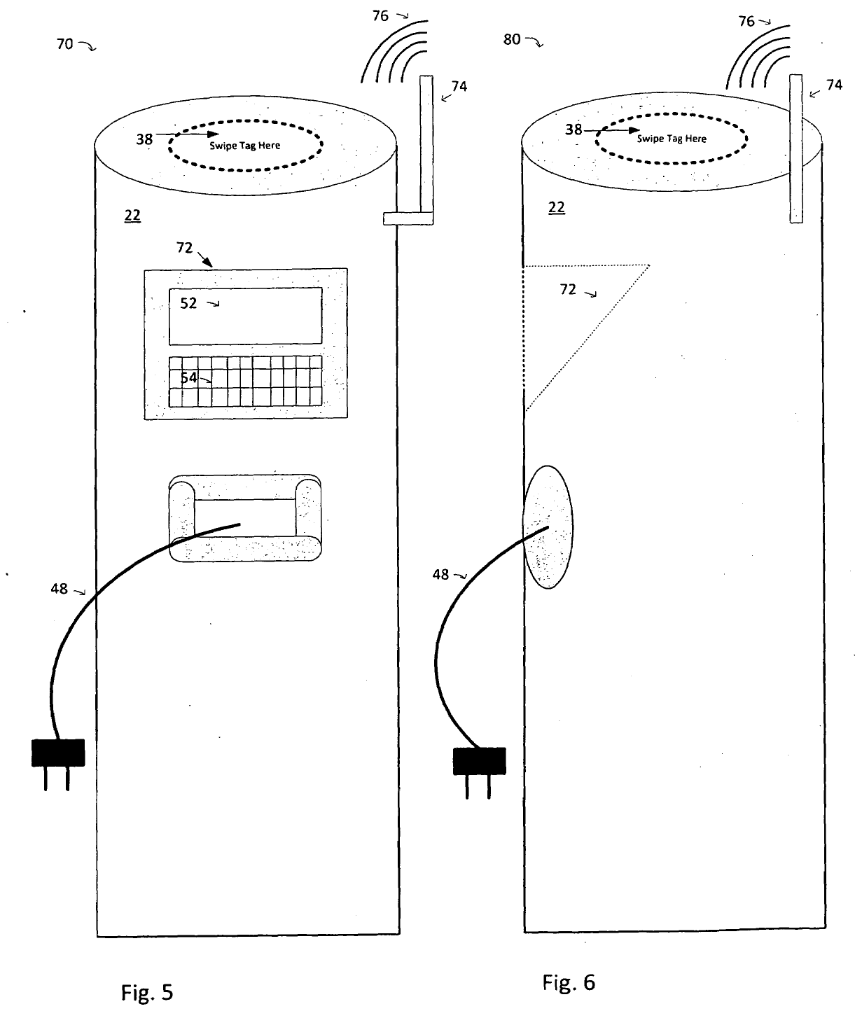

Referring now to FIG. 5, there is shown one embodiment of a front view 70 of the metering device 22 in accordance with one aspect of the present invention. The metering device has a recessed user interface 72 consisting of the visual display 52 and the user input system 54 (which may be embodied in one device, for example a touchscreen). At the top of the metering device 22 there is located the identification sensor 38. In one embodiment, the retractable power cord 48 that connects the metering device 22 with the vehicle electrical power system 26 is located on the front of the metering device 22, however users may establish this electrical connection in a different manner (such as wirelessly or via an outlet with a user-supplied electrical cord). In one embodiment, an external antenna 74 transmits data wirelessly, although data transfer may occur over any data connection and the antenna 74 could be internal.

Referring now to FIG. 6, there is shown one embodiment of a side view 80 of the metering device 22 in accordance with one aspect of the present invention. The metering device has a recessed user interface 72 consisting of the visual display 52 and the user input system 54 (which may be embodied in one device, for example a touchscreen). At the top of the metering device 22 there is located the identification sensor 38. In one embodiment, the retractable power cord 48 that connects the metering device 22 with the vehicle electrical power system 26 is located on the front of the metering device 22, however users may establish this electrical connection in a different manner (such as wirelessly or via an outlet with a user-supplied electrical cord). In one embodiment, an external antenna 74 transmits data wirelessly, although data transfer may occur over any data connection and the antenna 74 could be internal.

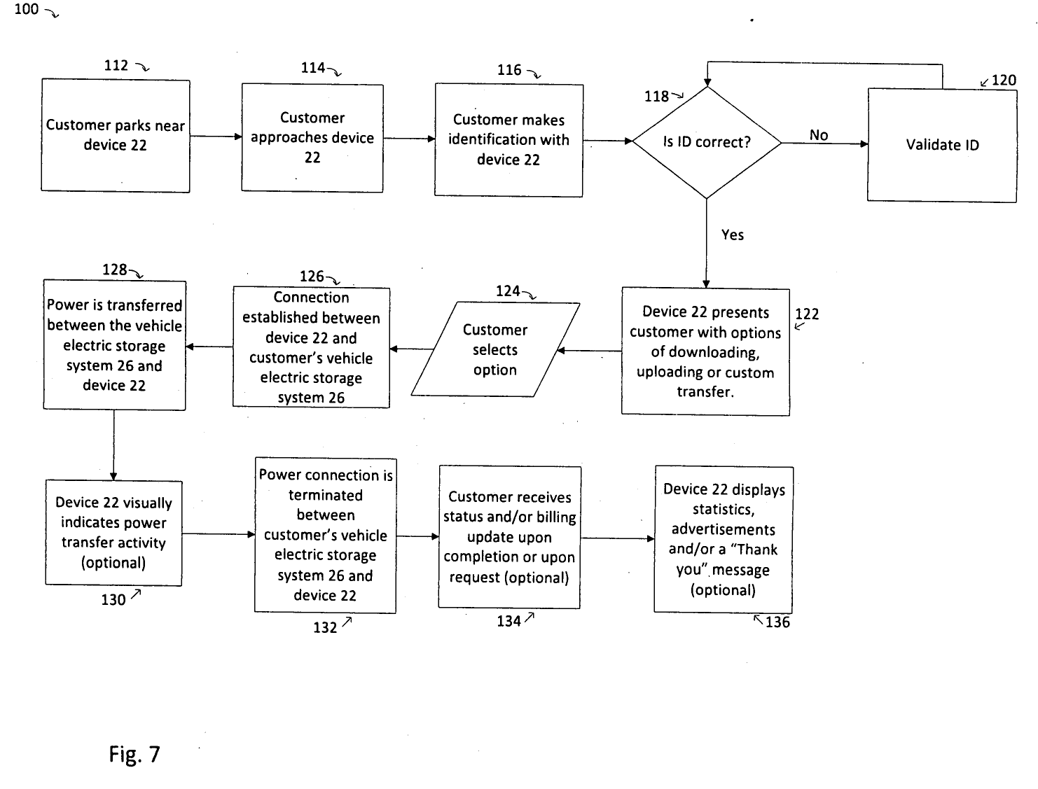

Referring now to FIG. 7, there is shown a high level flow diagram 100 of the user experience with the metering device 22 in accordance with one aspect of the present invention. At step 112, a customer parks his or her vehicle near the metering device 22. At step 114, the customer approaches the metering device 22 and at step 116 makes identification with the metering device 22 through either the identification sensor 38 located on the top of the metering device 22 or through the user interface 72 located on the front of the metering device 22. At decision 118, the user must determine if the user ID shown on the visual display 52 is correct, and if not, continue the verification process in step 120. In step 120 the user may be asked additional verification questions or asked to re-input their user ID.

At step 122, the metering device 22 then presents the customer with options such as the option to Download Electric Current from Power Grid, Upload Electric Current from Vehicle, or Custom Electric Current Transfer. At input 124, the customer selects one of the available options. At step 126, a connection is established between the metering device 22 and the vehicle electrical power system 26 through power cord 48. At step 128, power is transferred between the metering device 22 and the vehicle electrical power system 26. At optional step 130, the metering device 22 indicates the power transfer activity to the customer. At step 132, when the customer has downloaded sufficient power from the power grid 14, the customer has uploaded the maximum power to the power grid 14 to ensure that they can still drive to their next destination, or the customer has to leave because of time constraints, the power connection between the customer's vehicle electrical power system 26 and the metering device 22 is terminated and the power cord 48 may retract back into the metering device 22. In optional step 134, upon completion of the transaction or upon user request, the metering device sends a status and/or billing update to the customer via text message or email or displays the update on the display 52 of the user interface 72. At optional step 136, the metering device 22 may display statistics, advertisements or other related or non related material, and or a “Thank You” message on the visual display 52 and the transaction is complete.

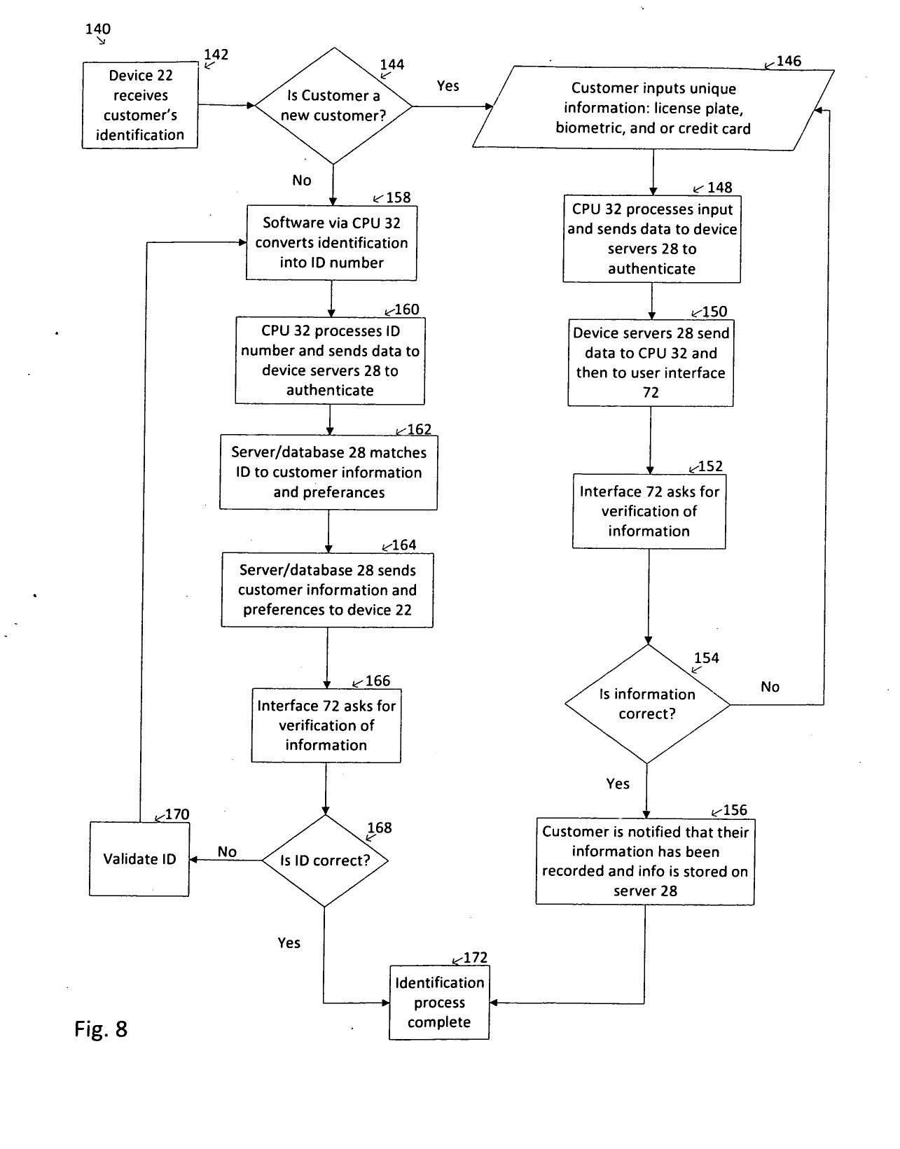

Referring now to FIG. 8, there is shown a detailed flow diagram 140 of the customer identification methodology controlled by the CPU 32 in the metering device 22 in accordance with one aspect of the present invention. At step 142, the metering device 22 receives the customer identification from step 118 in FIG. 7. In decision 144, the CPU 32 determines if the customer is a new customer based on the identification received.

If the customer is a new customer with a customer profile not already in the server/database 28, in input step 146 the customer inputs his or her unique information, such as their vehicle license plate number, biometrics, and/or credit card information. In step 148, the CPU 32 processes the input and sends the data to the metering device servers/database 28 for authentication. In step 148, the device servers 28 send the data back to the CPU 32 and display the information on the display 52 of the user interface 72 for authentication. In step 152, the user interface asks for verification of information. In decision 154, the customer determines if the information displayed is correct. If it is, the customer is notified in step 156 that their information has been recorded and a new customer profile and ID number is created and stored on the server/database 28, and the identification process is complete in step 172. If the information is not correct, the customer is returned to input 146 and is asked to re-input their information and continue the process described above.

If the customer is not a new customer and already has a customer profile, in step 158 the software in the metering device 22 via CPU 32 coverts the customer identification into the customer ID number. In step 160, the CPU 32 processes the ID number and sends the data to device server/database 28 for authentication. In step 162, the server/database 28 matches the customer ID number to customer information and preferences in the database 28. In step 164, the server/database 28 sends customer information and preferences to local metering device 22. In step 166, the user interface 72 asks for verification through display 52. In decision 168, if the information is incorrect, the customer then validates their ID in step 170, returning back to step 158. If the information is correct in decision 168, the identification process is complete in step 172.

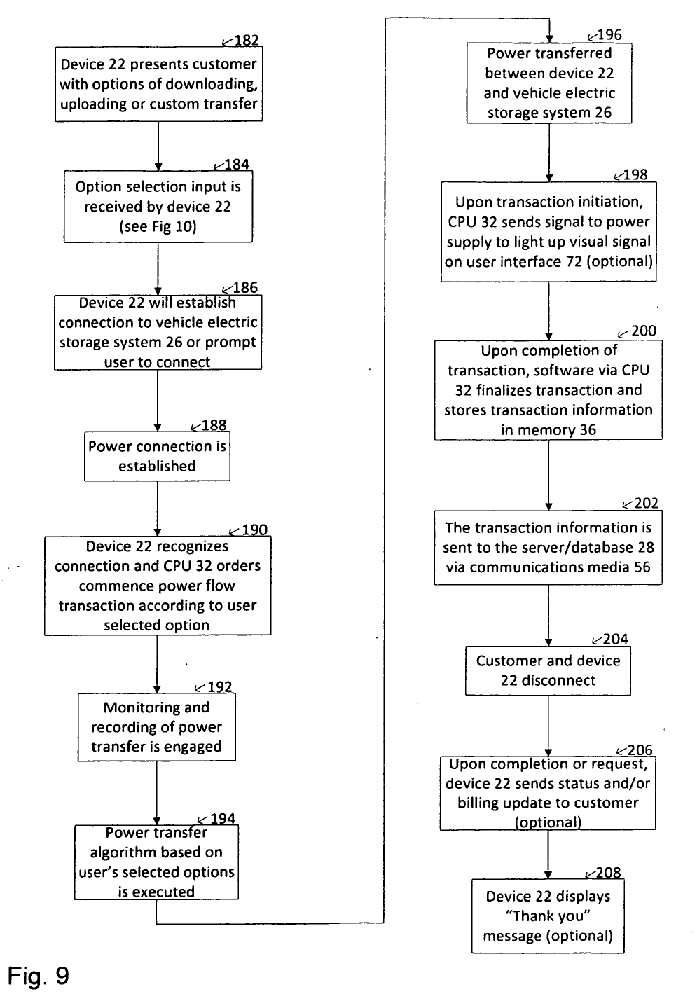

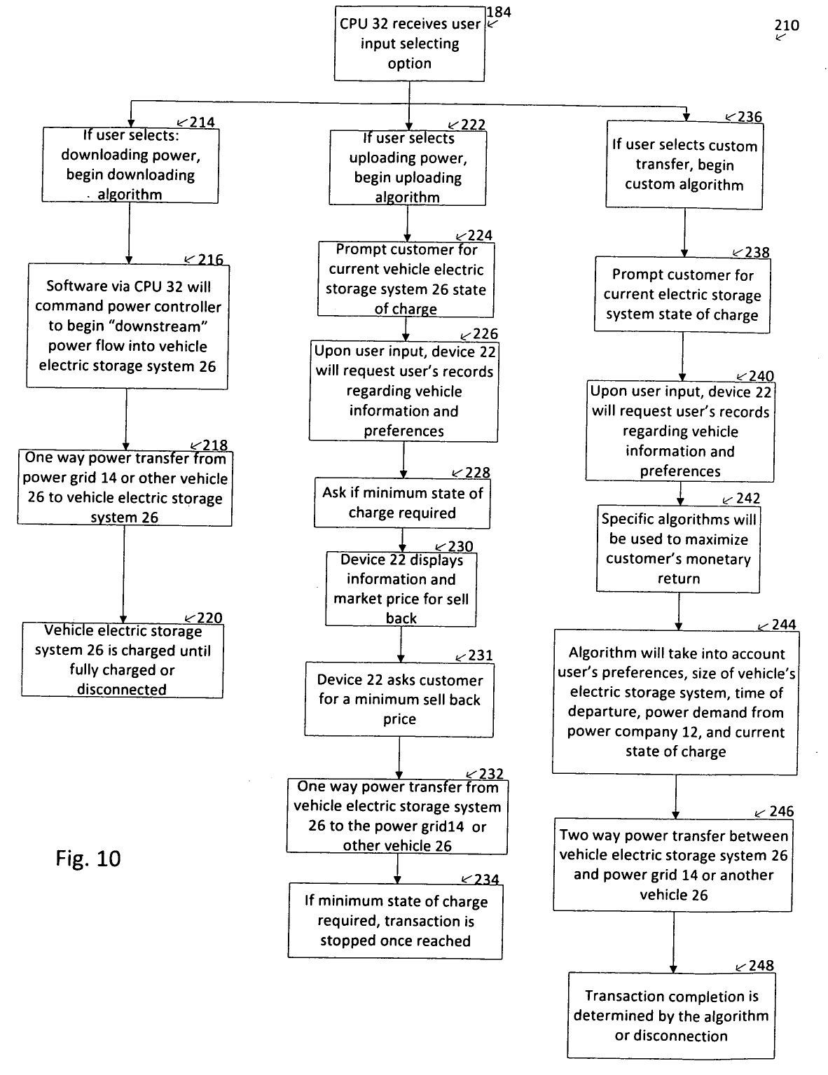

Referring now to FIG. 9, there is shown a detailed flow diagram 180 of the power transfer methodology in accordance with one aspect of the present invention. In step 182, the metering device 22 presents the customer with options such as the option to Download Electric Current from Power Grid, Upload Electric Current from Vehicle, or Custom Electric Current Transfer through display 52. In step 184, the metering device 22 and CPU 32 receives the option selected through user input system 54 (See FIG. 10, below, for detailed flow diagram descriptions for each option). In step 186, the metering device 22 will establish a connection to the vehicle electrical power system 26 or will prompt customer to connect the metering device 22 to the vehicle electrical power system 26 through the retractable power cord 48 or other electrical connection. In step 188, a power connection is established between the vehicle electrical power system 26 and the metering device 22. In step 190, the metering device 22 recognizes a connection and the CPU 32 orders uni-directional power controller 42 or bi-directional power controller 62 to commence power flow transactions according to user selected option in step 184.

In step 192, monitoring and recording of power transfer is engaged and the software via the CPU 32 receives continuous updates from the power meter 46 and records data to memory 36 for storage of transaction information. In step 194, the power transfer algorithm based on the user's selected options is executed, consisting of one of downloading, uploading, or a custom transfer (See FIG. 10, below, for detailed flow diagram descriptions for each option). In step 196, electrical energy is transferred between the metering device 22 and the vehicle electrical power system 26. In optional step 198, upon transaction initiation, the CPU 32 sends a signal to the power supply 34 to light up a visual signal on the display 52 of the user interface 72 to visually indicate power transfer activity to the customer. In step 200, upon completion of the transaction, software via the CPU 32 finalizes the transaction and stores record of transaction on the memory 36. In step 202, the transaction information is sent to the server/database 28 via communications media 56 in order to update the customer's user account, which may then be linked to the user's bank account or credit card, depending on the amount of electrical energy purchased from the grid 14 or another vehicle 26 or sold to the grid 14 or another vehicle 26. In step 204, the customer and the metering device 22 are disconnected and the retractable power cord 48 may be returned to the front of the metering device 22. In optional step 206, upon completion of the transaction or upon user request, the metering device sends a status and/or billing update to the customer via text message or email or displays the update on the display 52 of the user interface 72. Finally, in optional step 208, the metering device 22 displays a “Thank You” or similar message and the transaction is complete.

Referring now to FIG. 10, there is shown a detailed flow diagram 210 of the power transfer method options listed in step 184 of FIG. 9 in accordance with one aspect of the present invention. In step 184, the CPU 32 receives the input from the user-selected option of one of downloading, uploading, or a custom transfer.

If the user selects the download power option from the power grid 14 or from another vehicle 26 to their vehicle 26, the downloading algorithm begins in step 214. In step 216, software via the CPU 32 will command the bi-directional power controller 62 to begin “downstream” power flow from power grid 14 or from another vehicle 26 through metering device 22 and into vehicle electrical power system 26. In step 218, power is transferred from the power grid 14 or other vehicle 26 to the vehicle electrical power system 26. In step 220, the vehicle electrical power system 26 is charged until the electrical power system 26 is fully charged or disconnected by the user. The current will be measured in a predetermined amount, such as kilowatt-hours (kWh). The customer will be charged according to the amount of current transferred.

If the user selects the upload power option from the vehicle electrical power system 26 to the power grid 14 or to another vehicle 26, the uploading algorithm begins in step 222. In step 224, the metering device 22 will prompt the customer for the current state of charge of their vehicle electrical power system 26 through display 52 of user interface 72. In step 226, upon user input through user input system 54, the metering device 22 will request the user's records regarding vehicle information and preferences from the server/database 28 via the communications media 56. In step 228, the metering device 22 will ask the user if a minimum state of charge is required in order for the customer to be able to drive to their next destination. In step 230, the metering device 22 displays the customer's information and the current market sell back price via the display 52. In step 231 the user may specify a minimum selling price or elect to sell at the current market price. If the user selects a minimum selling price, the uploading algorithm will prevent transfer unless that minimum selling price is obtained. In step 232, the one-way power transfer from the vehicle electrical power system 26 to the power grid 14 or to another vehicle 26 is initiated. The CPU 32 requests the bi-directional power controller 62 to send power back through the metering device 22 and to the power grid 14 or to another vehicle 26. The power meter 46 will record the amount of current transferred and will send this information to the CPU 32 to store in memory 36. The current will be measured in a predetermined amount, such as kilowatt-hours (kWh) and the customer will be credited according to the amount transferred. In step 234, if the minimum state of charge required is met or user terminates the connection, the transaction is stopped and the data from the transfer is transmitted to the server/database 28.

If the user selects the custom transfer option, the custom algorithm begins in step 236. In step 238, the metering device 22 will prompt the customer for the current state of charge of their vehicle electrical power system 26 through display 52 of user interface 72. In step 240, upon user input through user input system 54, the metering device 22 will request the user's records regarding vehicle information and preferences from the server/database 28 via the communications media 56. In step 242, the software via the CPU 32 will utilize specific algorithms to maximize the customer's monetary return. In step 244, the algorithms will take into account the user's preferences and other variables including but not limited to the current market price and demand, the time of the day, the capacity of the vehicle electrical power system 26, the time of departure, the current state of charge of the electric storage system, and the electrical energy transfer rate, which may be uploaded from the server/database 28 to the metering device 22 or may be requested from the user upon transaction setup. The user may also indicate a minimum selling price as shown in step 231. In step 246, the CPU 32 requests the bi-directional power controller 62 to direct power from the vehicle through the metering device 22 and into the power grid 14 or another vehicle 26 at the specific time the algorithm determines the customer's monetary profit will be maximized. The CPU 32 also requests the bi-directional power controller 62 to direct power from the power grid 14 or another vehicle 26 through the metering device 22 to the vehicle electrical power system 26 at the specific time the algorithm determines the customer's monetary expense will be minimized. The power meter 46 will record the amount of current transferred and will send this information to the CPU 32 to store in memory 36. The current will be measured in a predetermined amount, such as kilowatt-hours (kWh) and the customer will be credited or debited according to the amount uploaded or downloaded respectively. In step 248, if the algorithm determines that minimum state of charge is about to be required then electrical energy will be transferred to attain the minimum state of charge based on the user's preferences. When each transaction is complete, the data from the transfer is transmitted to the server/database 28.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

What is claimed is:

1. A metering device, comprising:
a first interface configured to electrically couple to an electrical power system of a vehicle;
a meter coupled to the first interface and configured to measure electrical energy transmitted to or from the vehicle electrical power system; and
a module having an associated module identification (ID) and configured to generate a signal indicative of the measured electrical energy in association with the module ID.

2. The metering device as specified in claim 1 further comprising a second interface configured to couple to a power grid at an access point and transmit the measured electrical energy to or from the power grid or another vehicle.

3. The metering device as specified in claim 2 further comprising a processing module configured to exchange data with a physically remote processing center as a function of the signal.

4. The metering device as specified in claim 3 wherein the data includes a parameter, the parameter comprising at least one of the following: time of day, access point information, and location of access point.

5. The metering device as specified in claim 1 further comprising a sensor configured to receive a user ID.

6. The metering device as specified in claim 5 wherein the user ID is associated with an account.

7. The metering device as specified in claim 1 further comprising a display configured to display information that is a function of the measured electrical energy.

8. The metering device as specified in claim 7 wherein the information is indicative of the measured electrical energy.

9. The metering device as specified in claim 5 wherein the sensor is configured to receive the user ID from a portable object including the user ID.

10. The metering device as specified in claim 3 wherein the processing center is a banking system.

11. The metering device as specified in claim 1 further comprising a database configured to store a user's information, account history, and preferences associated with both downloading and uploading the electrical energy to and from, respectively, the vehicle electrical power system.

12. The metering device as specified in claim 11 wherein the preference is a function of time of day.

13. The metering device as specified in claim 11 wherein the preference is a function of a price of the electrical energy.

14. A computer readable medium including instructions for enabling a meter device to:
receive a user ID associated with an account;
verify the user ID;
receive a user-inputted option to either download or upload electrical energy to or from, respectively, a vehicle electrical power system;
process the user-inputted option;
establish an electrical connection between the vehicle electrical power system and a power grid; and
meter the transfer of electrical energy via the device.

15. The computer readable medium as specified in claim 14 further comprising instructions for recording the electrical energy transferred.

16. The computer readable medium as specified in claim 15 further comprising instructions for associating the recorded electrical energy transferred with the user ID and account.

17. The computer readable medium as specified in claim 15 further comprising instructions for enabling a display to display information that is a function of the measured electrical energy.

18. The computer readable medium as specified in claim 14 further comprising instructions for exchanging data with the vehicle.

19. The computer readable medium as specified in claim 18 further comprising instructions enabling the meter to send data indicative of the metered transfer of electrical energy.

20. The computer readable medium as specified in claim 19 further comprising instructions enabling the meter to send data as a function of parameters including access point information.

21. The computer readable medium as specified in claim 18 further comprising instructions enabling the meter to exchange data selected from the group of:
user account information, command functions, logs, history information, video files, audio files, executable files, and configuration files.

22. The computer readable medium as specified in claim 18 further comprising instructions enabling the meter to exchange data including financial information including user credit or debit data.

23. A method for meter to meter a bi-directional transfer of energy between a vehicle electric power system and a power grid or another vehicle, the method comprising the steps of:
receiving a request of an electrical energy transfer;
processing the request;
transmitting electrical energy to or from the vehicle electric power system and the power grid or another vehicle; and
measuring the electrical energy transferred in a predetermined unit of measurement.

24. The method of claim 23 wherein the measured electrical energy units are recorded and stored in a server database.

25. The method of claim 23 further comprising the steps of the meter exchanging data with the vehicle.

26. The method of claim 25 wherein the data is selected from the group of:
user account information, command functions, logs, history information, video files, audio files, executable files, and configuration files.

27. The method of claim 25 wherein the data is financial information including user credit or debit data.
